(19) United States
(12) Patent Application Publication
(10) Pub. No.: US 2015/0225848 A1
(43) Pub. Date: Aug. 13, 2015

(54) SUBSTRATE TREATMENT APPARATUS AND SUBSTRATE TREATMENT METHOD

(71) Applicant: JUSUNG ENGINEERING CO. LTD., Gwangiu-su, Gyeonggi-do (KR)

(72) Inventors: Jeung Hoon Han, Gwangju-si (KR); Young Hoon Kim, Uiwang-sii (KR); Chul Joo Hwang, Seongnam-si (KR)

(21) Appl. No.: 14/422,685

(22) PCT Filed: Aug. 23, 2013
(86) PCT No.: PCT/KR2013/007593

§ 371 Date: Feb. 19, 2015

(30) Foreign Application Priority Data
Aug. 23, 2012 (KR) 10-2012-0092504

(51) Int. Cl. C23C 16/455; C23C 16/50; C23C 16/458

(52) U.S. Cl. CPC C23C 16/455; C23C 16/458; C23C 16/50

(57) ABSTRACT

Disclosed is an apparatus and method for processing substrate, which is capable of realizing uniformity of a thin film deposited on a substrate, and facilitating quality control for the thin film, wherein the apparatus includes a process chamber, a chamber lid, a substrate supporter for supporting at least one of substrates, a source gas distributor for distributing source gas to a source gas distribution area, a reactant gas distributor for distributing reactant gas to a reactant gas distribution area, a purge gas distributor for distributing purge gas to a purge gas distribution area defined between the source gas distribution area and the reactant gas distribution area, wherein a distance between the purge gas distributor and the substrate is relatively smaller than a distance between the substrate and each of the source gas distributor and reactant gas distributor.

### CROSS REFERENCE TO RELATED APPLICATIONS

This application claims the benefit of the Korean Patent Application No. 10-2012-0092504 filed on Aug. 23, 2012, which is hereby incorporated by reference as if fully set forth herein.

### BACKGROUND

1. Field of the Invention

The present invention relates to an apparatus and method of processing substrate which deposits a thin film on a substrate.

2. Discussion of the Related Art

Generally, in order to manufacture a solar cell, a semiconductor device and a flat panel display device, it is necessary to form a predetermined thin film layer, a thin film circuit pattern or an optical pattern on a surface of a substrate. Thus, a semiconductor manufacturing process may be carried out, for example, a thin film deposition process of depositing a thin film of a predetermined material on a substrate, a photo process of selectively exposing the thin film by the use of photosensitive material, and an etching process of forming a pattern by selectively removing an exposed portion of the thin film.

The semiconductor manufacturing process is performed inside a substrate processing apparatus designed to be suitable for optimal circumstances. Recently, a substrate processing apparatus using plasma is generally used to carry out a deposition or etching process.

This semiconductor manufacturing process using plasma may be a PECVD (Plasma Enhanced Chemical Vapor Deposition) apparatus for forming a thin film, and a plasma etching apparatus for etching and patterning the thin film.

FIG. 1 illustrates an apparatus of processing substrate (substrate processing apparatus) according to the related art.

Referring to FIG. 1, the substrate processing apparatus according to the related art may include a chamber 10, a plasma electrode 20, a susceptor 30, and a gas distributing means 40.

The chamber 10 provides a process space for substrate processing. In this case, a predetermined portion of a bottom surface of the chamber 10 is communicated with a pumping port 12 for discharging process gas from the process space.

The plasma electrode 20 is provided over the chamber 10 so as to seal the process space.

One side of the plasma electrode 20 is electrically connected with a RF (Radio Frequency) power source 24 through a matching member 22. The RF power source 24 generates RF power, and supplies the generated RF power to the plasma electrode 20.

Also, a central portion of the plasma electrode 20 is communicated with a gas supply pipe 26 supplying the process gas for the substrate processing.

The matching member 22 is connected between the plasma electrode 20 and the RF power source 24, to thereby match load impedance and source impedance of the RF power supplied from the RF power source 24 to the plasma electrode 20.

The susceptor 30 is provided inside the chamber 10, and the susceptor 30 supports a plurality of substrates (W) loaded from the external. The susceptor 30 corresponds to an opposite electrode in opposite to the plasma electrode, and the susceptor 30 is electrically grounded by an elevating axis 32 for elevating the susceptor 30.

Inside the susceptor 30, there is a substrate heating means (not shown) for heating the supported substrate (W). According as the susceptor 30 is heated by the substrate heating means, a lower surface of the substrate (W) supported by the susceptor 30 is also heated.

The elevating axis 32 is moved up and down by an elevating apparatus (not shown). In this case, the elevating axis 32 is surrounded by a bellows 34 for sealing the elevating axis 32 and the bottom surface of the chamber 10.

The gas distributing means 40 is provided below the plasma electrode 20, wherein the gas distributing means 40 confronts with the susceptor 30. In this case, a gas diffusion space 42 is formed between the gas distributing means 40 and the plasma electrode 20. Inside the gas diffusion space 42, the process gas supplied from the gas supply pipe 26 penetrating through the plasma electrode 20 is diffused. The gas distributing means 40 uniformly distributes the process gas to the entire area of the process space through a plurality of gas distributing holes 44 being communicated with the gas diffusion space 42.

In case of the substrate processing apparatus according to the related art, after the substrate (W) is loaded onto the susceptor 30, the substrate (W) loaded onto the susceptor 30 is heated, the predetermined process gas is distributed to the process space of the chamber 10, and the RF power is supplied to the plasma electrode 20 so as to form the plasma in the process space, whereby a predetermined thin film is formed on the substrate (W). During the thin film deposition process, the process gas distributed to the process space flows toward the edge of the susceptor 30, and then the process gas is discharged out of the chamber 10 through the pumping port 12 formed at both sides of the bottom surface of the chamber 10.

However, in case of the substrate processing apparatus according to the related art, a density of the plasma formed on the entire area of the susceptor 30 is not uniform so that uniformity of the thin film material deposited on the substrate (W) is deteriorated, and it is difficult to control quality of the thin film.

Furthermore, the source and reactant gases are mixed together in the process space, and the predetermined thin film is formed on the substrate (W) by CVD (Chemical Vapor Deposition), whereby the properties of thin film is not uniform and thus it is difficult to control quality of the thin film.

### SUMMARY

Accordingly, the present invention is directed to an apparatus and method of processing substrate that substantially obviates one or more problems due to limitations and disadvantages of the related art.

An aspect of the present invention is to provide an apparatus and method of processing substrate, which is capable of realizing uniformity of a thin film deposited on a substrate, and facilitating quality control for the thin film.

Additional advantages and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these and other advantages and in accordance with the purpose of the invention, as embodied and broadly described herein, there is provided a substrate processing apparatus that may include a process chamber for preparing a process space; a chamber lid for covering an upper side of the process chamber; a substrate supporter for supporting at least one of substrates, wherein the substrate supporter is provided in the process chamber, a source gas distributor for distributing source gas to a source gas distribution area defined on the substrate supporter, wherein the source gas distributor is provided in the chamber lid; a reactant gas distributor for distributing reactant gas to a reactant gas distribution area defined on the substrate supporter, wherein the reactant gas distributor is provided in the chamber lid; and a purge gas distributor for distributing purge gas to a purge gas distribution area defined between the source gas distribution area and the reactant gas distribution area, wherein the purge gas distributor is provided in the chamber lid, wherein a distance between the purge gas distributor and the substrate is relatively smaller than a distance between the substrate and each of the source gas distributor and reactant gas distributor.

In another aspect of the present invention, there is provided a substrate processing method for depositing a thin film on a substrate by a mutual reaction of source gas and reactant gas inside a process space prepared in a process chamber that may include placing at least one substrate on a substrate supporter provided inside the process chamber; distributing the source gas to a source gas distribution area defined on the substrate supporter; distributing the reactant gas to a reactant gas distribution area defined on the substrate supporter; and distributing purge gas to a purge gas distribution area defined between the source gas distribution area and the reactant gas distribution area so as to spatially separate the source gas distribution area and the reactant gas distribution area from each other, wherein a distribution distance of the purge gas to the substrate is relatively shorter than each distribution distance of the source gas and the reactant gas to the substrate.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a substrate processing apparatus according to the related art;

FIG. 2 is a perspective view illustrating a substrate processing apparatus according to the first embodiment of the present invention;

FIG. 3 is a plane view illustrating the substrate processing apparatus according to the first embodiment of the present invention;

FIG. 4 is a cross sectional view along I-I of FIG. 3;

FIG. 5 illustrates a gap between a substrate and each of source gas distributor, reactant gas distributor and purge gas distributor;

FIG. 6 is a plane view illustrating a substrate processing apparatus according to the second embodiment of the present invention;

FIG. 7 is a plane view illustrating a substrate processing apparatus according to the third embodiment of the present invention;

FIG. 8 is a perspective view illustrating a substrate processing apparatus according to the fourth embodiment of the present invention;

FIG. 9 is a plane view illustrating the substrate processing apparatus according to the fourth embodiment of the present invention;

FIG. 10 is a cross sectional view along II-II′ of FIG. 9;

FIG. 11 is a cross sectional view illustrating a first modified example of the source gas distribution module in the substrate processing apparatus according to the first to fourth embodiments of the present invention;

FIG. 12 is a cross sectional view illustrating a second modified example of the source gas distribution module in the substrate processing apparatus according to the first to fourth embodiments of the present invention;

FIG. 13 is a plane view illustrating a substrate processing apparatus according to the fifth embodiment of the present invention;

FIG. 14 is a cross sectional view along III-III′ of FIG. 13; and

FIG. 15 is a plane view illustrating the purge gas distributor shown in FIG. 14.

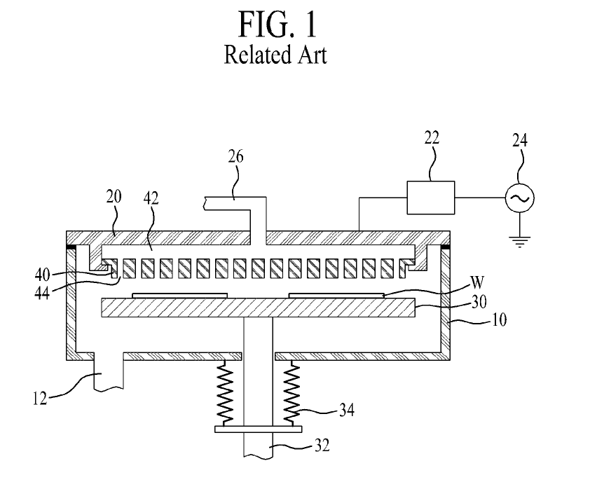

### DETAILED DESCRIPTION OF THE INVENTION

Hereinafter, embodiments of the present invention will be described in detail with reference to the accompanying drawings.

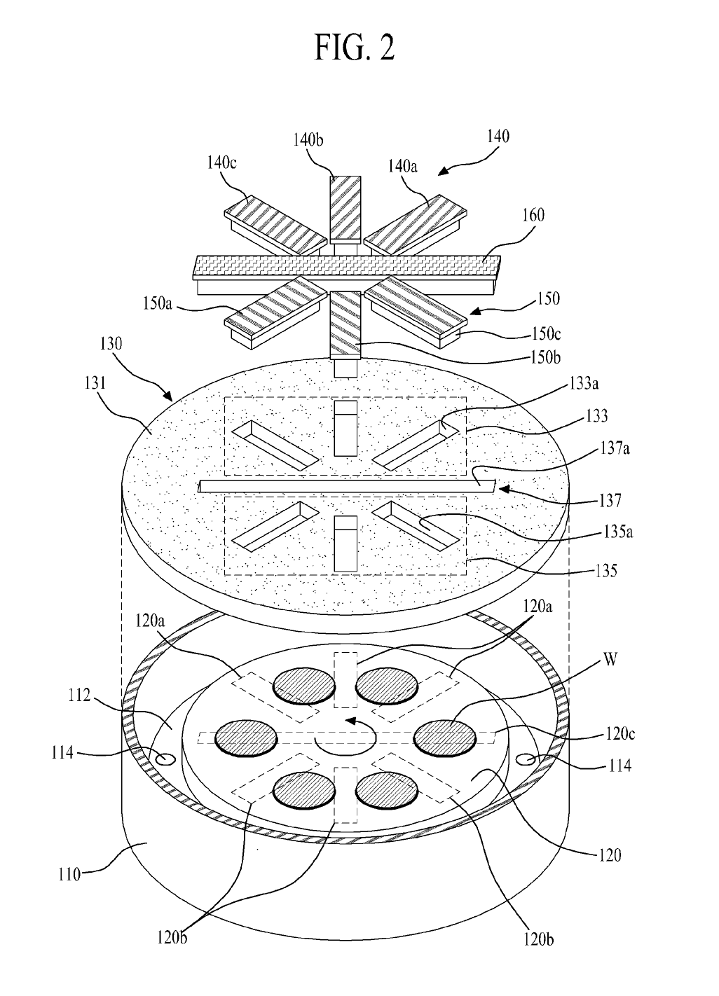

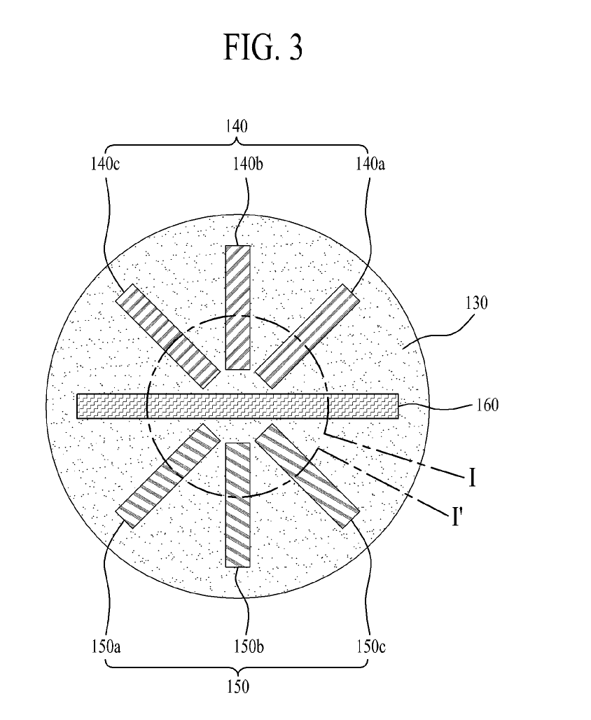

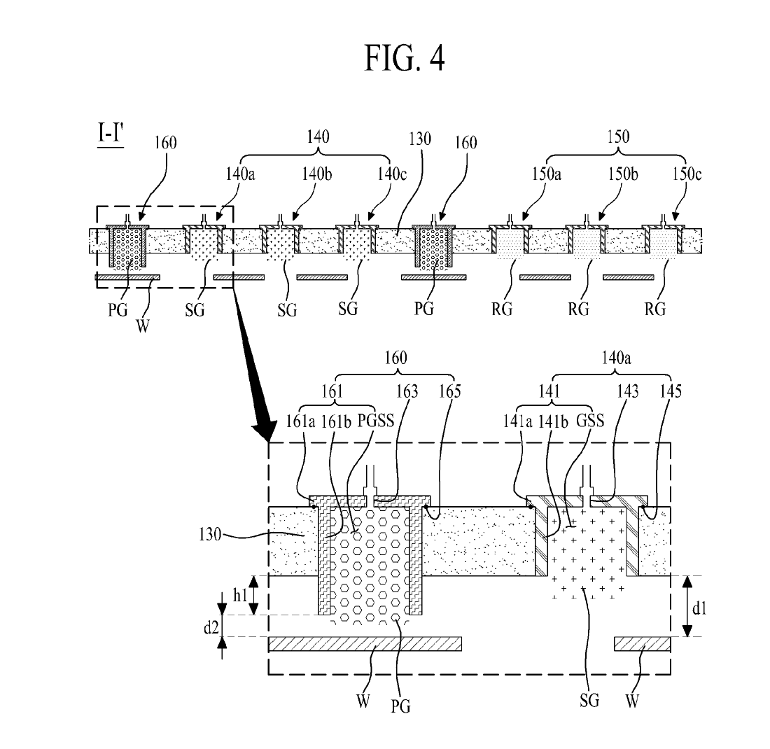

FIG. 2 is a perspective view illustrating a substrate processing apparatus according to the first embodiment of the present invention. FIG. 3 is a plane view illustrating the substrate processing apparatus according to the first embodiment of the present invention. FIG. 4 is a cross sectional view along I-I of FIG. 3.

Referring to FIGS. 2 to 4, the substrate processing apparatus according to the first embodiment of the present invention may include a process chamber 110, a substrate supporter 120, a chamber lid 130, a source gas distributor 140, a reactant gas distributor 150, and a purge gas distributor 160.

The process chamber 110 provides a process space for substrate processing, for example, a thin film deposition process. To this end, the process chamber 110 may include a bottom surface, and a chamber sidewall, which is vertical to the bottom surface, for defining the process space.

On the bottom surface of the process chamber 110, there is a bottom frame 112. The bottom frame 112 may include a guide rail (not shown) for guiding a rotation of the substrate supporter 120, and a pumping port 114 for pumping gas of the process space to the outside. The plurality of pumping ports 114 may be arranged at fixed intervals in a pumping pipe (not shown) formed in a circular-shaped band inside the bottom frame 112 being adjacent to the chamber sidewall, whereby the plurality of pumping ports 114 may be communicated with the process space.

A substrate doorway (not shown) through which the substrate (W) is loaded into or unloaded from the process space is formed in at least one chamber sidewall of the process chamber 110. The substrate doorway (not shown) may include a chamber sealing means (not shown) for sealing the inside of the process space.

The substrate supporter 120 is provided on the internal bottom surface of the process chamber 110, that is, the bottom frame 112. The substrate supporter 120 supports at least one substrate (W) which is loaded into the process space from an external substrate loading apparatus (not shown) through the substrate doorway. In this case, the substrate supporter 120 is formed in a disk shape, and is electrically grounded or floating. The substrate (W) may be a semiconductor substrate or wafer. Preferably, the plurality of substrates (W) may be arranged at fixed intervals in a circular pattern on the substrate supporter 120 so as to improve the yield.

A plurality of substrate-placing areas on which the plurality of substrates (W) are respectively placed may be provided on the upper surface of the substrate supporter 120. Each of the plural substrate-placing areas (not shown) may be provided with a plurality of align marks (not shown) formed on the upper surface of the substrate supporter 120, or may be provided in a concave pocket shape with a predetermined depth from the upper surface of the substrate supporter 120. The substrate (W) is loaded onto the substrate-placing area (not shown) by the substrate loading apparatus, wherein an identification means (not shown) for showing the lower side of the substrate (W) is formed at one side of the substrate (W). Accordingly, the substrate loading apparatus detects the identification means formed at one side of the substrate (W), aligns a loading position of the substrate (W) through the use of identification means, and loads the aligned substrate onto the substrate-placing area (not shown). Thus, the lower side of the substrate (W) placed onto the substrate supporter 120 is positioned adjacent to the edge of the substrate supporter 120, and the upper side of the substrate (W) is positioned adjacent to the center of the substrate supporter 120. The identification means may be used as a reference point in various test processes for the substrate (W) which completes a substrate treatment process.

The substrate supporter 120 may be movably or fixedly provided on the bottom frame 112. If the substrate supporter 120 is movably provided on the bottom frame 112, the substrate supporter 120 moves in a predetermined direction (for example, counterclockwise direction) with respect to the center of the bottom frame 112, that is, rotates in a predetermined direction. In this case, the edge of the substrate supporter 120 is guided by the guide rail formed in the bottom frame 112. To this end, a guide groove for insertion of the guide rail is formed in the edge of the lower surface of the substrate supporter 120.

The chamber lid 130 is provided on the process chamber 110, to thereby seal the process space. The chamber lid 130 supports the source gas distributor 140, the reactant gas distributor 150, and the purge gas distributor 160 which are detachably connected thereto. To this end, the chamber lid 130 may include a lid frame 131, and first to third module receivers 133, 135 and 137.

The lid frame 131, which is formed in a circular plate, covers the process chamber 110, to thereby seal the process space prepared by the process chamber 110.

The first module receiver 133 is formed at one side of the lid frame 131 so that the source gas distributor 140 is separably connected to and supported by the first module receiver 133. To this end, the first module receiver 133 may include a plurality of first module-receiving holes 133a which are provided at one side of the lid frame 131 with respect to the center of the lid frame 131 and are arranged at fixed intervals in a radial pattern. Each of the first module-receiving holes 133a having a rectangular-shaped plane penetrates through the lid frame 131.

The second module receiver 135 is formed at the other side of the lid frame 131 so that the reactant gas distributor 150 is separably connected to and supported by the second module receiver 135. To this end, the second module receiver 135 may include a plurality of second module-receiving holes 135a which are provided at the other side of the lid frame 131 with respect to the center of the lid frame 131 and are arranged at fixed intervals in a radial pattern. Each of the second module-receiving holes 135a having a rectangular-shaped plane penetrates through the lid frame 131.

The above-mentioned first module-receiving holes 133a, the second module-receiving module holes 135a and the third module receiver 137 are provided in the lid frame 131, wherein the first module-receiving holes 133a, the second module-receiving module holes 135a and the third module receiver 137 are provided in such a manner that the first module-receiving holes 133a and second module-receiving holes 135a are symmetric with respect to the third module receiver 137.

The third module receiver 137 is formed in the center of the lid frame 131, that is, the third module receiver 137 is positioned between the first module receiver 133 and the second module receiver 135, wherein the third module receiver 137 supports the purge gas distributor 160 being separably connected thereto. To this end, the third module receiver 137 may include a third module-receiving hole 137a which is provided in the center of the lid frame 131 and is formed in a rectangular shape.

The third module-receiving hole 137a having a rectangular-shaped plane penetrates through the center of the lid frame 131, wherein the third module-receiving hole 137a traverses the center of the lid frame 131 between the first module receiver 133 and the second module receiver 135.

In FIG. 2, the chamber lid 130 includes three of the first module-receiving holes 133a and three of the second module-receiving holes 135a, but not limited to this structure. The chamber lid 130 may include two or more of the first module-receiving holes 133a and two or more of the second module-receiving holes 135a. In the following description for the substrate processing apparatus according to the first embodiment of the present invention, it is assumed that the chamber lid 130 includes three of the first module-receiving holes 133a and three of the second module-receiving holes 135a.

The above process chamber 110 and chamber lid 130 may be formed in the circular structure shown in FIG. 2, but not limited to this structure. For example, the process chamber 110 and the chamber lid 130 may be formed in a polygonal structure such as a hexagonal structure, or may be formed in an elliptical structure. If forming the polygonal structure such as the hexagonal structure, the process chamber 110 may be divided into a plurality of sections, and the plurality of sections may be combined to one another.

The source gas distributor 140 is separably connected to the first module receiver 133 of the chamber lid 130, whereby source gas (SG) is distributed on the substrate (W) which is sequentially moved by the substrate supporter 120. That is, the source gas distributor 140 locally distributes the source gas (SG) to a plurality of source gas distribution areas 120a defined in the space between the chamber lid 130 and the substrate supporter 120, downwardly. Thus, according to driving of the substrate supporter 120, the source gas (SG) is distributed on the substrate (W) which passes the space below the plurality of source gas distribution areas 120a. To this end, the source gas distributor 140 may include first to third source gas distribution modules 140a, 140b and 140c for downwardly distributing the source gas (SG), wherein the first to third source gas distribution modules 140a, 140b and 140c may be detachably connected to the plurality of first module-receiving holes 133a.

Each of the first to third source gas distribution modules 140a, 140b and 140c may include a gas distribution frame 141, a plurality of gas supply holes 143, and a sealing member 145.

The gas distribution frame 141 is formed in a case shape having a lower-side opening, and the gas distribution frame 141 is detachably inserted into the first module-receiving hole 133a. That is, the gas distribution frame 141 may include a ground plate 141a being detachably connected to the lid frame 131 adjacent to the first module-receiving hole 133a by the use of bolt, and a ground sidewall 141b vertically protruding from the lower edge of the ground plate 141a and being inserted into the first module-receiving hole 133a. The gas distribution frame 141 is electrically grounded through the lid frame 131.

The lower surface of the gas distribution frame 141, that is, the lower surface of the ground sidewall 141b is positioned at the same height as the lower surface of the chamber lid 130 so that the lower surface of the gas distribution frame 141 is provided at a first distance (d1) from the upper surface of the substrate (W) supported by the substrate supporter 120. Meanwhile, the lower surface of the ground sidewall 141b may protrude out of the lower surface of the chamber lid 130 toward the substrate supporter 120 by the properties of thin film deposition so that the lower surface of the ground sidewall 141b may be positioned at a predetermined height from the lower surface of the chamber lid 130, that is, the lower surface of the ground sidewall 141b may be provided at a predetermined distance from the upper surface of the substrate (W).

The plurality of gas supply holes 143, which penetrate through the upper surface of the gas distribution frame 141, that is, the ground plate 141a, are communicated with a gas distribution space (GSS) prepared inside the gas distribution frame 141. The plurality of gas supply holes 143 supply the source gas (SG), which is supplied from an external gas supply apparatus (not shown), to the gas distribution space (GSS) so as to downwardly distribute the source gas (SG) to the source gas distribution area 120a through the gas distribution space (GSS). The source gas (SG) being downwardly distributed to the source gas distribution area 120a flows toward the pumping port 114 prepared at the lateral side of the substrate supporter 120 with respect to the center of the substrate supporter 120.

The source gas (SG) includes a thin film material to be deposited on the substrate (W). The source gas (SG) may be the gas of silicon (Si), titanium family element (Ti, Zr, Hf, and etc.), or aluminum (Al). For example, the source gas (SG) including the thin film material of silicon (Si) may be the gas selected from Silane (SiH4), Disilane (Si2H6), Trisilane (Si3H8), TEOS (Tetraethylorthosilicate), DCS (Dichlorosilane), HCD (Hexachlorosilane), TriDMAS (Tri-dimethylaminosilane), TSA (Trisilylamine), and etc. The source gas (SG) may further contain non-reactive gas such as nitrogen (N2) gas, argon (Ar) gas, xenon (Ze) gas, or helium (He) gas according to the deposition properties of the thin film to be deposited on the substrate (W).

The sealing member 145 seals the space between the gas distribution frame 141 and the chamber lid 130, that is, the space between the gas distribution frame 141 and the first module-receiving hole 133a, wherein the sealing member 145 may be formed of an O-ring.

The reactant gas distributor 150 is separably connected to the second module receiver 135 of the chamber lid 130, whereby reactant gas (RG) is distributed on the substrate (W) which is sequentially moved by the substrate supporter 120. That is, the reactant gas distributor 150 locally distributes the reactant gas (RG) to a plurality of reactant gas distribution areas 120b which are spatially separated from the above source gas distribution areas 120a and are defined in the space between the chamber lid 130 and the substrate supporter 120, downwardly. Thus, according to driving of the substrate supporter 120, the reactant gas (RG) is distributed on the substrate (W) which passes the space below the plurality of reactant gas distribution areas 120b. To this end, the reactant gas distributor 150 may include first to third reactant gas distribution modules 150a, 150b and 150c for downwardly distributing the reactant gas (RG), wherein the first to fourth reactant gas distribution modules 150a, 150b and 150c may be detachably connected to the plurality of second module-receiving holes 135a.

Each of the first to third reactant gas distribution modules 150a, 150b and 150c is detachably provided in the second module-receiving hole 135a of the chamber lid 130, and each of the first to third reactant gas distribution modules 150a, 150b and 150c downwardly distributes the reactant gas (RG), which is supplied from the external gas supply apparatus (not shown), to the reactant gas distribution area 120b. In the same manner as the above first to third source gas distribution modules 140a, 140b and 140c, each of the first to third reactant gas distribution modules 150a, 150b and 150c may include a gas distribution frame 141, a plurality of gas supply holes 143, and a sealing member 145, whereby a detailed description for elements included in each of the first to third reactant gas distribution modules 150a, 150b and 150c will be substituted by the above description for those included in each of the source gas distribution modules 140a, 140b and 140c.

In the reactant gas distributor 150, the lower surface of the gas distribution frame 141, that is, a lower surface of a ground sidewall 141b is positioned at the same height as the lower surface of the chamber lid 130 so that the lower surface of the gas distribution frame 141 is provided at a first distance (d1) from the upper surface of the substrate (W) supported by the substrate supporter 120. Meanwhile, the lower surface of the ground sidewall 141b may protrude out of the lower surface of the chamber lid 130 toward the substrate supporter 120 by the properties of thin film deposition so that the lower surface of the ground sidewall 141b may be positioned at a predetermined height from the lower surface of the chamber lid 130, that is, the lower surface of the ground sidewall 141b may be provided at a predetermined distance from the upper surface of the substrate (W). In this case, the distance between the lower surface of the source gas distributor 140 and the upper surface of the substrate (W) may be the same as or different from the distance between the lower surface of the reactant gas distributor 150 and the upper surface of the substrate (W).

The reactant gas (RG) being downwardly distributed from the reactant gas distributor 150 to the reactant gas distribution area 120b flows toward the pumping port 114 prepared at the lateral side of the substrate supporter 120 with respect to the center of the substrate supporter 120.

The reactant gas (RG) includes some of the thin film material to be deposited on the substrate (W), wherein the reactant gas (RG) reacts with the source gas (SG), to thereby form the thin film. The reactant gas (RG) may contain hydrogen (H2) gas, nitrogen (N2) gas, oxygen (O2) gas, nitrogen dioxide (NO2) gas, ammonia (NH3) gas, steam (H2O) gas, or ozone (O3) gas. In this case, the reactant gas (RG) may further contain non-reactive gas such as nitrogen (N2) gas, argon (Ar) gas, xenon (Ze) gas, or helium (He) gas according to the deposition properties of the thin film to be deposited on the substrate (W).

The source gas (SG) distributed from the source gas distributor 140 may be different in quantity from the reactant gas (RG) distributed from the reactant gas distributor 150, which enables to adjust a reaction rate of the source gas (SG) and reactant gas (RG) on the substrate (W). In this case, each source gas distribution module included in the above source gas distributor 140 may be different in size from each reactant gas distribution module included in the above reactant gas distributor 150, or the number of source gas distribution modules included in the source gas distributor 140 may be different from the number of reactant gas distribution modules included in the reactant gas distributor 150.

The purge gas distributor 160 is separably connected to the third module receiver 137 of the chamber lid 130, whereby purge gas (PG) is downwardly distributed to the process space of the process chamber 110 between the source gas distributor 140 and the reactant gas distributor 150, to thereby form a gas barrier for spatially separating the source gas (SG) from the reactant gas (RG), and thus preventing the source gas (SG) and the reactant gas (RG) from being mixed together. That is, the purge gas distributor 160 downwardly distributes the purge gas (PG) to a purge gas distribution area 120c, which is defined in the area between the source gas distribution area 120a and the reactant gas distribution area 120b inside the space between the chamber lid 130 and the substrate supporter 120, to thereby form the gas barrier which enables to prevent the source gas (SG) and the reactant gas (RG) from being mixed during the distribution process. To this end, the purge gas distributor 160 may include a housing 161, a plurality of purge gas supply holes 163, and a sealing member 165.

The housing 161 is formed in a rectangular case shape whose bottom is opened, wherein the housing 161 is detachably inserted into the third module-receiving hole 137a. That is, the housing 161 may include a housing plate 161 being separably provided in the lid frame 131 adjacent to the third module-receiving hole 137a through the use of bolt, and a housing sidewall 161b vertically protruding from the lower edge of the housing plate 161a so as to prepare the purge gas distribution space (PGSS), wherein the housing sidewall 161b is inserted into the third module-receiving hole 137a.

The lower surface of the housing 161, that is, the lower surface of the housing sidewall 161b may protrude out of the lower surface of the chamber lid 130 toward the substrate supporter 120, whereby the protruding height of the housing sidewall 161b may be a predetermined height (h1). Thus, the lower surface of the housing 161 is provided at a predetermined distance (d2) from the upper surface of the substrate (W) supported by the substrate supporter 120. In this case, the second distance (d2) between the lower surface of the purge gas distributor 160 and the upper surface of the substrate (W) is relatively smaller than the first distance (d1) between the lower surface of the source gas distributor 140 and the upper surface of the substrate (W) or between the lower surface of the reactant gas distributor 150 and the upper surface of the substrate (W).

The plurality of purge gas supply holes 163, which penetrate through the upper surface of the housing 161, that is, the housing plate 161a, are communicated with the purge gas distribution space (PGSS) prepared inside the housing 161. The plurality of purge gas supply holes 163 supply the purge gas (PG), which is supplied from an external gas supply apparatus (not shown), to the purge gas distribution space (PGSS) so as to downwardly distribute the purge gas (PG) to the purge gas distribution area 120c through the purge gas distribution space (PGSS), thereby forming the gas barrier between the source gas distribution area 120a and the reactant gas distribution area 120b, enabling a flow of the source gas (SG), distributed to the source gas distribution area 120a, toward the pumping port 114 prepared at the lateral side of the substrate supporter 120, and also enabling a flow of the reactant gas (RG), distributed to the reactant gas distribution area 120b, toward the pumping port 114 prepared at the lateral side of the substrate supporter 120.

The purge gas (PG) may contain the non-reactive gas such as nitrogen (N2) gas, argon (Ar) gas, xenon (Ze) gas, or helium (He) gas.

The sealing member 165 seals the space between the housing 161 and the chamber lid 130, that is, the space between the housing 161 and the third module-receiving hole 137a, wherein the sealing member 165 may be formed of an O-ring.

The purge gas distributor 160 is provided in such a manner that a distance between the purge gas distributor 160 and the substrate supporter 120 is relatively smaller than each distance between the source gas distributor 140 and the substrate supporter 120 and between the reactant gas distributor 150 and the substrate supporter 120. Thus, a distribution distance of the purge gas (PG) from the purge gas distributor 160 to the purge gas distribution area 120c is relatively smaller (for example, about the half or less) than each distribution distance of the source gas (SG) and the reactant gas (RG) so that it is possible to prevent the source gas (SG) and the reactant gas (RG) from being mixed when the source gas (SG) and the reactant gas (RG) are distributed to the substrate (W). For example, the distribution distance of the purge gas (PG) is less than half the distance of the distribution distance of the source gas (SG). In this case, a distribution pressure of the purge gas (PG) distributed from the purge gas distributor 160 may be higher than each distribution pressure of the source gas (SG) and the reactant gas (RG). The relatively-higher distribution pressure of the purge gas (PG) facilitates the division of space between the source gas (SG) and the reactant gas (RG).

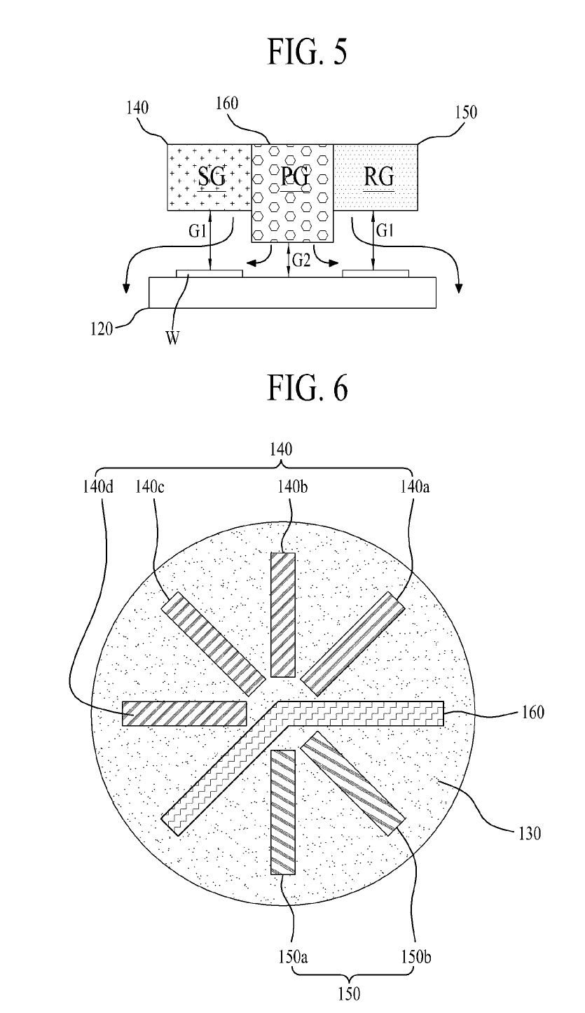

In detail, as shown in FIG. 5, when the source gas distributor 140 and the reactant gas distributor 150 are arranged above the substrate supporter 120, each distance between the source gas distributor 140 and the substrate supporter 120 and between the reactant gas distributor 150 and the substrate supporter 120 corresponds to a first gas (G1). Meanwhile, when the purge gas distributor 160 is arranged above the substrate supporter 120, the distance between the purge gas distributor 160 and the substrate supporter 120 corresponds to a second gas (G2) which is relatively smaller than the first gas (G1). Accordingly, the purge gas (PG) distributed from the purge gas distributor 160 enables the flow of source gas (SG) and reactant gas (RG) toward the above-mentioned pumping port (See ‘114’ of FIG. 2) so that it is possible to prevent the source gas (SG) and the reactant gas (RG) from being mixed during the process of distributing the source gas (SG) and the reactant gas (RG) to the substrate (W). Thus, according as the plurality of substrates (W) are moved by the driving of the substrate supporter 120, each of the substrates (W) is sequentially exposed to the source gas (SG) and the reactant gas (RG) which are separated from each other by the purge gas (PG), whereby a single-layered or multi-layered thin film is deposited on each substrate (W) by ALD (Atomic Layer Deposition) in accordance with a mutual reaction of the source gas (SG) and the reactant gas (RG). In this case, the thin film may be a high dielectric film, an insulating film, a metal film, and etc.

A substrate processing method using the above substrate processing apparatus according to the first embodiment of the present invention will be briefly described as follows.

First, the plurality of substrates (W) are loaded at fixed intervals onto the substrate supporter 120, and are placed thereon.

While the plurality of substrates (W) being provided below the chamber lid 130 move in the predetermined direction (for example, the counterclockwise direction) according to the driving of the substrate supporter 120 with the plurality of substrates (W) loaded thereonto, the purge gas (PG) is downwardly distributed from the above purge gas distributor 160 to the purge gas distribution area 120c, the source gas (SG) is downwardly distributed from the above source gas distributor 140 to the source gas distribution area 120a, and the reactant gas (RG) is downwardly distributed from the above reactant gas distributor 150 to the reactant gas distribution area 120b, at the same time. Owing to the purge gas (PG), the source gas (SG) is spatially separated from the reactant gas (RG) without being mixed with the reactant gas (RG) inside the process space, whereby the source gas (SG) and the reactant gas (RG) being spatially separated from each other flow toward the pumping port 114 through the space above the substrate supporter 120. Each substrate (W) sequentially passes the source gas distribution area 120a, the purge gas distribution area 120c and the reactant gas distribution area 120b at a predetermined moving speed in accordance with the driving of the substrate supporter 120, to thereby form the single-layered or multi-layered thin film on each substrate (W) by the ALD process in accordance with the mutual reaction of the source gas (SG) and the reactant gas (RG).

As mentioned above, the substrate processing apparatus according to the first embodiment of the present invention and the substrate processing method using the same prevents the source gas (SG) and the reactant gas (RG) distributed to the substrate supporter 120 from being mixed together through the use of purge gas (PG), to thereby carry out the ALD process for each of the substrates (W) in accordance with the driving of the substrate supporter 120. Thus, the substrate processing apparatus according to the first embodiment of the present invention and the substrate processing method using the same enables to realize uniformity in quality properties of the thin film deposited on the substrate (W), and to facilitates the quality control of the thin film deposited on the substrate (W). Especially, in case of the substrate processing apparatus according to the first embodiment of the present invention and the substrate processing method using the same, the substrate supporter 120 is driven at a speed of 1000 RPM or more. Thus, even though the moving speed of the substrate (W) is rapid, the purge gas (PG) enables to prevent the source gas (SG) and the reactant gas (RG) from being mixed together, whereby the ALD process for the substrate (W) is carried out at high speed.

FIG. 6 is a plane view illustrating a substrate processing apparatus according to the second embodiment of the present invention. The substrate processing apparatus of FIG. 6 is obtained by changing structures of source gas distributor 140, reactant gas distributor 150 and purge gas distributor in the above substrate processing apparatus according to the first embodiment of the present invention. Hereinafter, only the changed structures of the source gas distributor 140, reactant gas distributor 150 and purge gas distributor 160 will be described as follows.

In the above substrate processing apparatus according to the first embodiment of the present invention, the three gas distribution modules included in the source gas distributor 140 and the three gas distribution modules included in the reactant gas distributor 150 are symmetric with respect to the purge gas distributor 160.

Meanwhile, in case of the substrate processing apparatus according to the second embodiment of the present invention, the purge gas distributor 160 is positioned between gas distribution modules included in the source gas distributor 140 and gas distribution modules included in the reactant gas distributor 150, wherein the number of gas distribution modules included in the source gas distributor 140 is different from the number of gas distribution modules included in the reactant gas distributor 150. According to the deposition properties of thin film deposited on the substrate (W), the source gas (SG) distributed from the source gas distributor 140 may be different in quantity from the reactant gas (RG) distributed from the reactant gas distributor 150. In this reason, the number of gas distribution modules included in the source gas distributor 140 may be different from the number of gas distribution modules included in the reactant gas distributor 150. For example, the source gas distributor 140 may include four source gas distribution modules 140a, 140b, 140c and 140d for downwardly distributing source gas (SG), wherein the first to fourth source gas distribution modules 140a, 140b, 140c and 140d may be detachably connected to a chamber lid 130. Also, the reactant gas distributor 150 may include two reactant gas distribution modules 150a and 150b for downwardly distribution reactant gas (RG), wherein the two reactant gas distribution modules 150a and 150b may be detachably connected to the chamber lid 130.

Except that the purge gas distributor 160 is formed in “<” shape so as to spatially separate the source gas (SG) distributed from each source gas distribution module 140a, 140b, 140c and 140d of the source gas distributor 140 from the reactant gas (RG) distributed from each reactant gas distribution module 150a and 150b of the reactant gas distributor 150, and thus to prevent the source gas (SG) from being mixed with the reactant gas (RG), the purge gas distributor 160 according to the second embodiment of the present invention is identical to the above purge gas distributor 160 according to the first embodiment of the present invention.

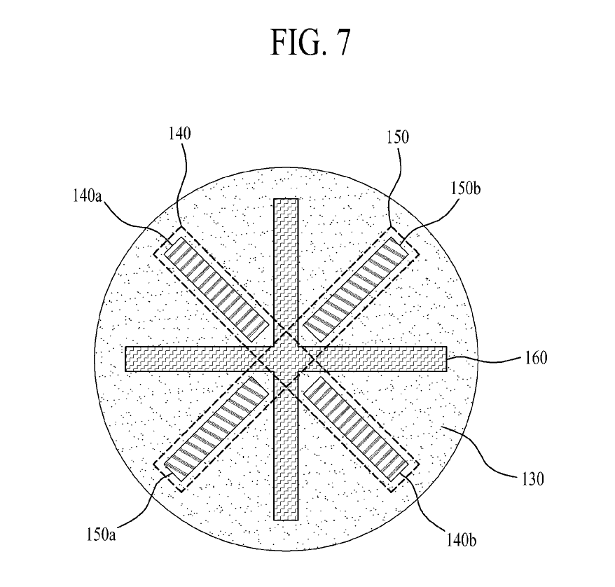

FIG. 7 is a plane view illustrating a substrate processing apparatus according to the third embodiment of the present invention. The substrate processing apparatus of FIG. 7 is obtained by changing arrangement structures of source gas distributor 140, reactant gas distributor 150 and purge gas distributor 160 in the above substrate processing apparatus according to the first embodiment of the present invention. Hereinafter, only the changed arrangement structures of the source gas distributor 140, reactant gas distributor 150 and purge gas distributor 160 will be described as follows.

In the substrate processing apparatus according to the first and second embodiments of the present invention, the purge gas distributor 160 is positioned between the source gas distributor 140 and the reactant gas distributor 150, whereby the source gas distribution area is prepared at one side of the purge gas distributor 160, and the reactant gas distribution area is prepared at the other side of the purge gas distributor 160.

Meanwhile, in case of the substrate processing apparatus according to the third embodiment of the present invention, when the source gas distributor 140 and the reactant gas distributor 150 are arranged in a chamber lid 130, source gas distribution modules 140a and 140b of the source gas distributor 140 alternates with reactant gas distribution modules 150a and 150b of the reactant gas distributor 150, and the purge gas distributor 160 is formed in shape of “+” or “×”, whereby the purge gas distributor 160 is positioned between each of the source gas distribution modules 140a and 140b and the reactant gas distribution modules 150a and 150b.

In detail, the source gas distributor 140 includes the first and second source gas distribution modules 140a and 140b which are arranged in a first diagonal direction with respect to the center of the chamber lid 130, and the reactant gas distributor 150 includes the first and second reactant gas distribution modules 150a and 150b which arranged in a second diagonal direction with respect to the center of the chamber lid 130, wherein the second diagonal direction is perpendicular to the first diagonal direction. Accordingly, when source gas distribution areas and reactant gas distribution areas are arranged on a substrate supporter 120, the source gas distribution areas being overlapped with the first and second source gas distribution modules 140a and 140b alternates with the reactant gas distribution areas being overlapped with the first and second reactant gas distribution modules 150a and 150b.

Each lower surface of the first and second source gas distribution modules 140a and 140b and the first and second reactant gas distribution modules 150a and 150b is provided at a first distance from the substrate (W) supported by the substrate supporter 120.

The purge gas distributor 160 is formed in shape of “+” or “×”, and the purge gas distributor 160 downwardly distributes purge gas (PG) to the space between each of the first and second source gas distribution modules 140a and 140b and the first and second reactant gas distribution modules 150a and 150b, thereby spatially separating the source gas distribution area from the reactant gas distribution area, and preventing the source gas (SG) and the reactant gas (RG) from being mixed together. In this case, as mentioned above, the lower surface of the purge gas distributor 160 protrudes out of the lower surface of the chamber lid 130 toward the substrate supporter 120, whereby the lower surface of the purge gas distributor 160 is provided at a predetermined distance from the substrate (W), for example, the predetermined distance between the lower surface of the purge gas distributor 160 and the substrate (W) is less than the half of the first distance between the substrate (W) and each of the source gas distributor 140 and the reactant gas distributor 150.

The substrate processing apparatus according to the third embodiment of the present invention and the substrate processing method using the same enables to form the thin film by the ALD process which prevents the mixture of source gas (SG) and reactant gas (RG) through the use of purge gas (PG), and alternately exposes the plurality of substrates (W) to the source gas (SG) and the reactant gas (RG) in accordance with the driving of the substrate supporter 120.

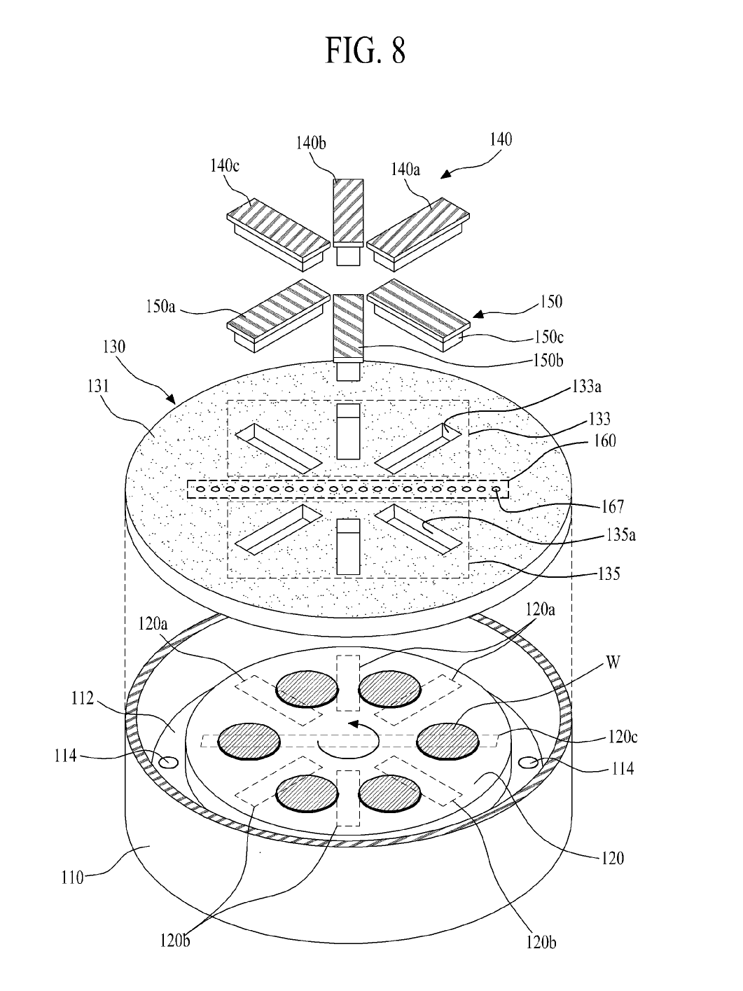

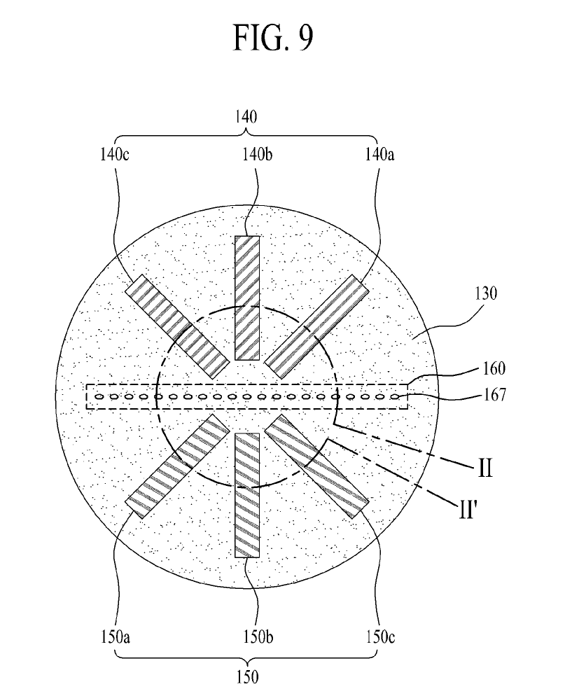

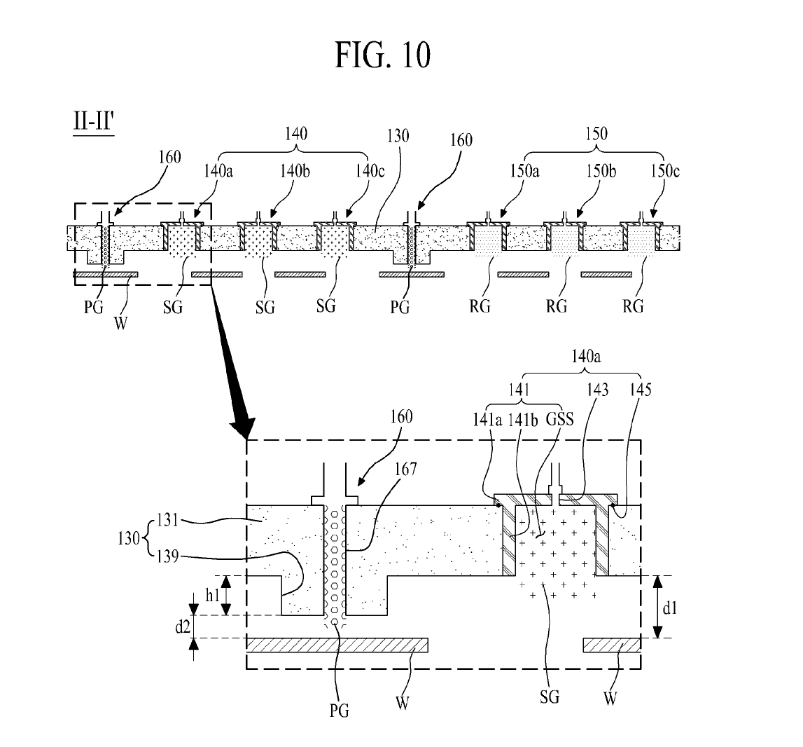

FIG. 8 is a perspective view illustrating a substrate processing apparatus according to the fourth embodiment of the present invention, FIG. 9 is a plane view illustrating the substrate processing apparatus according to the fourth embodiment of the present invention, and FIG. 10 is a cross sectional view along II-II′ of FIG. 9. The substrate processing apparatus according to the fourth embodiment of the present invention is obtained by changing a structure of a purge gas distributor 160 of a chamber lid 130 in the above substrate processing apparatus according to the first embodiment of the present invention. Hereinafter, only the structure of the purge gas distributor 160 of the chamber lid 130 will be described as follows.

First, the purge gas distributor 160 is included in the chamber lid 130, and a source gas distributor 140 and a reactant gas distributor 150 are detachably connected to and supported by the chamber lid 130. To this end, the chamber lid 130 includes a lid frame 131, a first module receiver 133, a second module receiver 135, and a protruding part 139. Except that the third module receiving hole 137a is substituted by the protruding part 139, the chamber lid 130 of the substrate processing apparatus according to the fourth embodiment of the present invention is identical to the above chamber lid 130 of the substrate processing apparatus according to the first embodiment of the present invention, whereby a detailed description for the same parts will be omitted.

The protruding part 139, which is formed in a rectangular shape having a predetermined width and a predetermined height (h1), protrudes from the center of the lower surface of the lid frame 131 toward a substrate supporter 120, wherein the protruding part 139 is arranged between the first module receiver 133 and the second module receiver 135. Accordingly, the lower surface of the protruding part 139 is provided at a second distance (d2) from the upper surface of the substrate (W) supported by the substrate supporter 120. The second distance (d2) between the protruding part 139 and the substrate (W) is less than the half of the above-mentioned first distance (d1) between the substrate (W) and each of the source gas distributor 140 and the reactant gas distributor 150.

In the above description, the rectangular-shaped protruding part 139 protrudes, but not limited to this structure. For example, the protruding part 139 may protrude to have “<”, “+” or “×” shape with the predetermined width and the predetermined height (h1), as shown in FIGS. 6 and 7 illustrating the substrate processing apparatus according to the second and third embodiments of the present invention.

The purge gas distributor 160 may include a plurality of purge gas distributing portions 167 for downwardly distributing the above-mentioned purge gas (PG), wherein the plurality of purge gas distributing portions may be provided at fixed intervals in the protruding part 139, and may be formed in shape of hole or slit.

Each of the purge gas distributing portions 167, which vertically penetrates through the protruding part 139, is communicated with a purge gas distribution area 120c defined on the substrate supporter 120 inside the process space. Each of the purge gas distributing portions 167 downwardly distributes the purge gas (PG), which is supplied form an external gas supply apparatus (not shown), to the purge gas distribution area 120c. Thus, in the same manner as the above embodiments of the present invention, a gas barrier of the purge gas (PG) is formed between the source gas distribution area 120a and the reactant gas distribution area 120b, whereby source gas (SG) and reactant gas (RG) respectively distributed to the source gas distribution area 120a and the reactant gas distribution area 120b flow towards a pumping port 114 prepared at the lateral side of the substrate supporter 120.

Meanwhile, the purge gas distributor 160 may be arranged between the source gas distributor 140 and the reactant gas distributor 150, and the number of gas distribution modules included in the source gas distributor 140 may be different from the number of gas distribution modules included in the reactant gas distributor 150. In this case, the shape of purge gas distributor 160 in the substrate processing apparatus according to the fourth embodiment of the present invention may be the same as the shape of purge gas distributor 160 shown in FIG. 6.

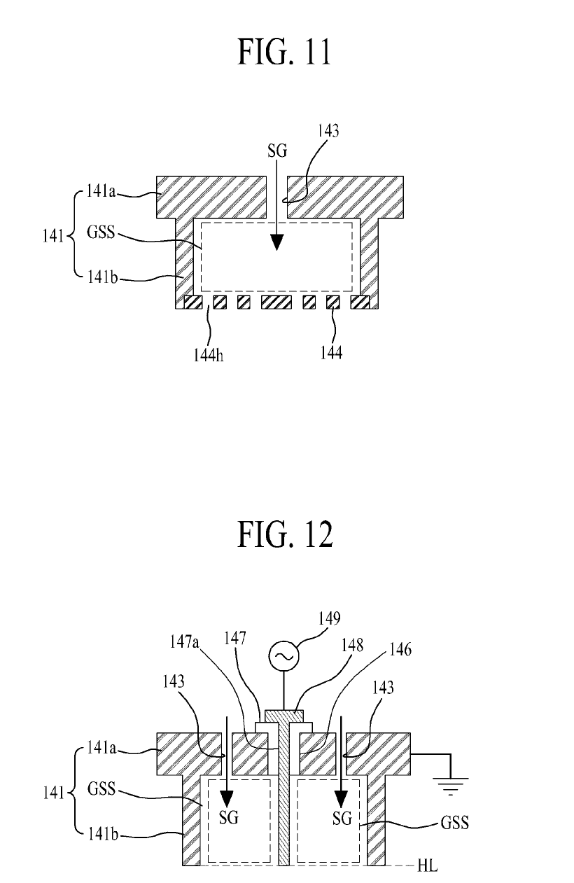

FIG. 11 is a cross sectional view illustrating a first modified example of the source gas distribution module in the substrate processing apparatus according to the first to fourth embodiments of the present invention, wherein the first modified example of the source gas distribution module is obtained by additionally forming a gas distribution pattern member 144. Hereinafter, only different structures will be described as follows.

Each gas distribution pattern member 144 of the source gas distribution module according to the first modified example of the present invention is provided in the aforementioned gas distribution space (GSS), wherein each gas distribution pattern member 144 increases a distribution pressure of source gas (SG) downwardly distributed to the substrate supporter 120. In this case, the gas distribution pattern member 144 may be formed as one body with the lower surface of the ground sidewall 141b for covering the lower side of the gas distribution space (GSS), or may be formed in an insulating plate (or shower head) of non-polarity insulating material and connected with the lower surface of the ground sidewall 141b for covering the lower side of the gas distribution space (GSS). Accordingly, the gas distribution space (GSS) is prepared between the ground plate 141a and the gas distribution pattern member 144, whereby the source gas (SG) supplied to the gas distribution space (GSS) through the aforementioned gas supply hole 143 is diffused and buffered inside the gas distribution space (GSS).

The gas distribution pattern member 144 may include a gas distribution pattern 144h for downwardly distributing the source gas (SG) of the gas distribution space (GSS) to the substrate (W).

The gas distribution pattern 144h may be provided with a plurality of holes (or a plurality of slits) penetrating through the gas distribution pattern member 144, wherein the plurality of holes arranged at fixed intervals downwardly distributes the source gas (SG) of the gas distribution space (GSS) at a predetermined pressure. In this case, a diameter of each of the holes and/or an interval between the holes may be determined within a range enabling the uniform gas distribution to the entire areas of the substrate (W) moving based on an angular speed in accordance with rotation of the substrate supporter 120. For example, the diameter of each hole may be designed in such a manner that the diameter of each hole is gradually increased from the inside of the gas distribution module which is adjacent to the center of the substrate supporter 120 to the outside of the gas distribution module which is adjacent to the edge of the substrate supporter 120.

The above gas distribution pattern member 144 downwardly distributes the source gas (SG) through the gas distribution pattern 144h, and the gas distribution pattern member 144 is formed in the plate shape having the holes so as to delay or slow down the flow of source gas (SG), thereby reducing gas consumption of the source gas (SG), and thus improving efficiency in using the source gas (SG).

The aforementioned gas distribution pattern member 144 may be provided in the lower surface of the gas distribution space (GSS) for each of the reactant gas distribution modules, whereby the reactant gas (RG) may be downwardly distributed at a predetermined pressure. Furthermore, the above gas distribution pattern member 144 may be provided in the lower surface of the housing 161 of the purge gas distributor 160, whereby the purge gas (PG) may be downwardly distributed at a predetermined pressure.

FIG. 12 is a cross sectional view illustrating a second modified example of the source gas distribution module in the substrate processing apparatus according to the first to fourth embodiments of the present invention, wherein the second modified example of the source gas distribution module is obtained by additionally forming a plasma electrode 148. Hereinafter, only different structures will be described as follows.

In the above substrate processing apparatus of the present invention, the source gas (SG), which is to be distributed to the substrate (W), is not activated. However, there is a need to activate the source gas (SG) in accordance with the kind of thin film to be deposited on the substrate (W), and to distribute the activated source gas on the substrate (W). Accordingly, the source gas distribution module according to the second modified example of the present invention activates the source gas (SG) by the use of plasma, and then distributes the activated source gas on the substrate (W).

In detail, each source gas distribution module according to the modified second example may further include the plasma electrode 148 being inserted into the gas distribution space (GSS). To this end, in case of each source gas distribution module, an insulating member insertion hole 146 being communicated with the gas distribution space (GSS) is formed in a ground plate 141a of a gas distribution frame 141, and an insulating member 147 is inserted into the insulating member insertion hole 146. Also, an electrode insertion hole 147a being communicated with the gas distribution space (GSS) is formed in the insulating member 147, and the plasma electrode 148 is inserted into the electrode insertion hole 147a.

The plasma electrode 148 is inserted into the gas distribution space (GSS), and is arranged in parallel to a ground sidewall 141b. In this case, the lower surface of the plasma electrode 148 may be positioned at the same line (HL) as the lower surface of the ground sidewall 141b, or the lower surface of the plasma electrode 148 may protrude out of the lower surface of the ground sidewall 141b, that is, the protruding portion of the plasma electrode 148 may have a predetermined height. The ground sidewall 141b functions as a ground electrode for forming plasma.

The plasma electrode 148 forms the plasma through the use of source gas (SG) supplied to the gas distribution space (GSS) in accordance with plasma power supplied from a plasma power supplier 149. In this case, the plasma is formed between the plasma electrode 148 and the ground electrode by an electric field formed therebetween in accordance with the plasma power. Accordingly, the source gas (SG) supplied to the gas distribution space (GSS) is activated by the plasma, and then the activated source gas is downwardly distributed on the substrate (W). In order to prevent the substrate (W) and/or thin film deposited on the substrate (W) from being damaged by the plasma, an interval (or gap) between the plasma electrode 148 and the ground electrode is smaller than an interval between the plasma electrode 148 and the substrate (W). Accordingly, the plasma is not formed between the substrate (W) and the plasma electrode 148, but is formed between the ground electrode and the plasma electrode 148 arranged in parallel and provided at the predetermined interval from the substrate (W), thereby preventing the substrate (W) and/or thin film from being damaged by the plasma.

The plasma power may be high frequency power or radio frequency (RF) power, for example, lower frequency (LF) power, middle frequency (MF) power, high frequency (HF) power, or very high frequency (VHF) power. In this case, the LF power may have 3 kHz˜300 kHz frequency, the MF power may have 300 kHz˜3 MHz frequency, the HF power may have 3 MHz˜30 MHz frequency, and the VHF power may have 30 MHz˜300 MHz frequency.

A feed cable for connecting the plasma electrode 148 and the plasma power supplier 149 may be connected with an impedance matching circuit (not shown). The impedance matching circuit matches load impedance and source impedance of the plasma power supplied from the plasma power supplier 149 to the plasma electrode 148. The impedance matching circuit may include at least two of impedance element (not shown) formed of at least one of variable capacitor and variable inductor.

The aforementioned plasma electrode 148 and insulating member 147 may be provided in the gas distribution space (GSS) for each reactant gas distribution module, whereby the reactant gas (RG) may be activated by the plasma, and downwardly distributed on the substrate (W). Furthermore, the aforementioned plasma electrode 148 and insulating member 147 may be provided in the housing 161 of the purge gas distributor 160 shown in FIGS. 2 to 4, whereby the purge gas (PG) may be activated by the plasma, and downwardly distributed on the substrate (W). According to the kind of thin film to be deposited on the substrate (W), the source gas (SG), the reactant gas (RG), and the purge gas (PG) may be distributed without being activated, or may be activated by the plasma and then distributed on the substrate (W). For example, the plasma electrode 148 is not formed in each of the source gas distribution modules and the purge gas distributor 160, as shown in FIG. 4, whereby the source gas (SG) and the purge gas (PG) are distributed without being activated. Meanwhile, the plasma electrode 148 is formed in each reactant gas distribution module, as shown in FIG. 12, whereby the reactant gas (RG) is activated by the plasma, and then distributed on the substrate (W).

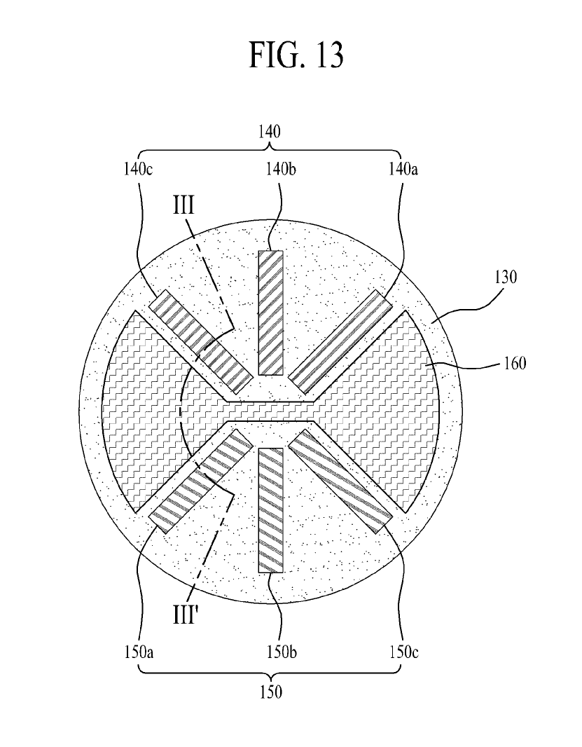

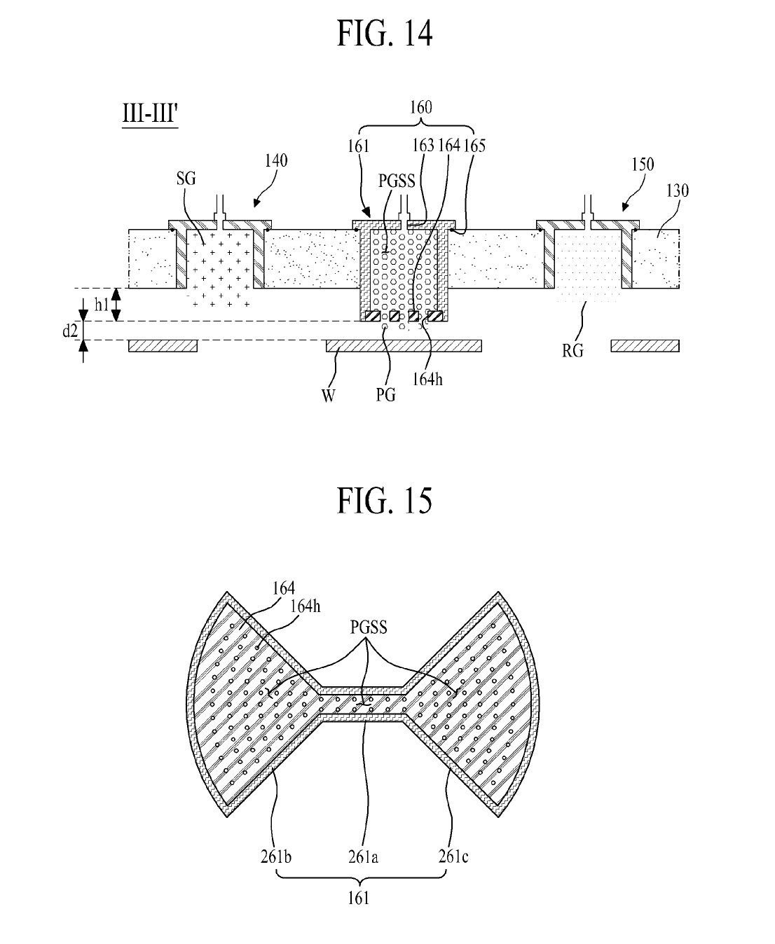

FIG. 13 is a plane view illustrating a substrate processing apparatus according to the fifth embodiment of the present invention, FIG. 14 is a cross sectional view along III-III′ of FIG. 13, and FIG. 15 is a plane view illustrating a purge gas distributor of FIG. 14. The purge gas distributor of FIG. 15 is obtained by changing a structure of the purge gas distributor 160 in the substrate processing apparatus according to the first embodiment of the present invention. Hereinafter, only the structure of the purge gas distributor 160 will be described as follows.

In the substrate processing apparatus according to the first embodiment of the present invention, the purge gas distributor 160 is formed in “−” plane shape.

In the substrate processing apparatus according to the fifth embodiment of the present invention, the purge gas distributor 160 is increased in size. Thus, even though a substrate supporter 120 is driven at a speed of 2000 RPM or more, it is possible to form the thin film on the substrate (W) by the ALD process without mixture of source gas (SG) and reactant gas (RG) distributed on the substrate (W).

In detail, the purge gas distributor 160 may include a housing 161, a purge gas supply hole 163, a purge gas distribution pattern member 164, and a sealing member 165.

The housing 161 is formed in a shape whose bottom is opened so that the housing 161 is detachably inserted into a third module receiver 137. In this case, the third module receiver 137 may include a third module-receiving hole whose shape is identical to that of the housing 161. The housing 161 may include a central frame 261a, a first-side frame 261b (provided at one side of the central frame 261a), and a second-side frame 261b (provided at the other side of the central frame 261a).

The central frame 261a is formed in a rectangular shape whose bottom is opened, wherein the central frame 261 confronts the center of the substrate supporter 120. The central frame 261a may include a central ground plate having a rectangle shape, and a central ground sidewall including a predetermined portion protruding out of the lower surface of the chamber lid 130, wherein the protruding portion of the central ground sidewall has a predetermined height (h1), and the central ground sidewall is formed at each of both sides of the central ground plate.

The first-side frame 261b is formed in a fan shape whose bottom is opened, and the first-side frame 261b is communicated with one side of the central frame 261a, wherein the first-side frame 261b confronts one side area with respect to the center of the substrate supporter 120. In this case, a size of the first-side frame 261b is relatively larger than a size of the central frame 261a. The first-side frame 261b may include a first-side ground plate which is formed in a fan shape and connected with one side of the central ground plate, and a first-side ground sidewall including a predetermined portion protruding out of the lower surface of the chamber lid 130, wherein the protruding portion of the first-side ground sidewall has a predetermined height (h1), and the first-side ground sidewall is formed at each of both sides of the first-side ground plate.

The second-side frame 261c is formed in a fan shape whose bottom is opened, and the second-side frame 261c is communicated with the other side of the central frame 261a, wherein the second-side frame 261c confronts the other side area with respect to the center of the substrate supporter 120. In this case, a size of the second-side frame 261c is relatively larger than a size of the central frame 261a. The second-side frame 261c may include a second-side ground plate which is formed in a fan shape and connected with the other side of the central ground plate, and a second-side ground sidewall including a predetermined portion protruding out of the lower surface of the chamber lid 130, wherein the protruding portion of the second-side ground sidewall has a predetermined height (h1), and the second-side ground sidewall is formed at each of both sides of the second-side ground plate.

Inside the housing 161, there is a purge gas distribution space (PGSS) which is surrounded by the central ground sidewall, the first-side ground sidewall and the second-side ground sidewall.

The purge gas supply hole 163, which penetrates through the upper surface of the housing 161, for example, the central ground plate, is communicated with the purge gas distribution space (PGSS) prepared inside the housing 161. The purge gas supply hole 163 enables to supply the purge gas (PG), which is supplied from an external gas supply apparatus (not shown), to the purge gas distribution space (PGSS).

The purge gas distribution pattern member 164 downwardly distributes the purge gas (PG) of the purge gas distribution space (PGSS) to a purge gas distribution area. To this end, the purge gas distribution pattern member 164 may be formed as one body with the lower surface of the housing 161, that is, the lower surface of the ground sidewall for covering the lower side of the purge gas distribution space (PGSS), or may be formed in an insulating plate (or shower head) of non-polarity insulating material and connected with the lower surface of the ground sidewall. Accordingly, the purge gas distribution space (PGSS) is prepared between the ground plates and the gas distribution pattern member 164, and the purge gas (PG) supplied to the purge gas distribution space (PGSS) through the aforementioned purge gas supply hole 163 is diffused and buffered inside the purge gas distribution space (PGSS).

The purge gas distribution pattern member 164 may include a purge gas distribution pattern 164h for downwardly distributing the purge gas (PG) of the purge gas distribution space (PGSS) to the substrate (W).

The purge gas distribution pattern 164h may be provided with a plurality of holes (or a plurality of slits) penetrating through the purge gas distribution pattern member 164, wherein the plurality of holes arranged at fixed intervals downwardly distribute the purge gas (PG) of the purge gas distribution space (PGSS) at a predetermined pressure. In this case, an interval between each hole of the purge gas distribution pattern 164h may be determined in consideration of a moving speed of the substrate (W) in accordance with a rotation of the substrate supporter 120. That is, the interval between each hole of the purge gas distribution pattern 164h may be designed in such a manner that the interval is gradually increased from the center of the substrate supporter 120 to the edge of the substrate supporter 120. Furthermore, the purge gas distribution pattern 164h may have the same diameter. In another aspect, the purge gas distribution pattern may be designed in consideration of a moving speed of the substrate (W) in accordance with a rotation of the substrate supporter 120. That is, the purge gas distribution pattern may be provided in such a manner that the diameter is gradually increased from the center of the substrate supporter 120 to the edge of the substrate supporter 120.

As mentioned above, the lower surface of the purge gas distribution pattern member 164 is provided at a second distance (d2) from the upper surface of the substrate (W) supported by the substrate supporter 120, to thereby prevent the source gas (SG) and the reactant gas (RG) from being mixed together. That is, the second distance (d2) between the lower surface of the purge gas distribution pattern member 164 and the upper surface of the substrate (W) is relatively smaller than the distance (d1) between the upper surface of the substrate (W) and each of the lower surface of the source gas distributor 140 and the lower surface of the reactant gas distributor 150.

The sealing member 165 seals the space between the housing 161 and the chamber lid 130, that is, the space between the housing 161 and third module receiver 137, wherein the sealing member 145 may be formed of an O-ring.

In the substrate processing apparatus according to the fifth embodiment of the present invention, the both sides of the purge gas distributor 160 are formed in the fan shape so that it is possible to increase the area of the purge gas distribution area. Thus, even though the substrate supporter 120 is driven at a speed of 20000 RPM or more, the thin film is deposited on the substrate (W) by the ALD process without the mixture of source gas (SG) and reactant gas (RG).

According to the present invention, the substrate processing apparatus and the substrate processing method enable to prevent the source gas (SG) and the reactant gas (RG) from being mixed during the gas distribution process to the substrate supporter 120.

Thus, the thin film is deposited on the substrate (W) moving in accordance with the driving of the substrate supporter 120 by the ALD process so that it is possible to realize uniformity in quality properties of the thin film deposited on the substrate (W), and to facilitates the quality control of the thin film deposited on the substrate (W).

Also, even though the substrate supporter 120 is driven at a speed of 1000 RPM or more, that is, the moving speed of the substrate (W) is rapid, it is possible to prevent the source gas (SG) and the reactant gas (RG) from being mixed together, whereby the ALD process for the substrate (W) is carried out at high speed.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A substrate processing apparatus comprising:
a process chamber for preparing a process space;
a chamber lid for covering an upper side of the process chamber;
a substrate supporter for supporting at least one of substrates, wherein the substrate supporter is provided in the process chamber,
a source gas distributor for distributing source gas to a source gas distribution area defined on the substrate supporter, wherein the source gas distributor is provided in the chamber lid;
a reactant gas distributor for distributing reactant gas to a reactant gas distribution area defined on the substrate supporter, wherein the reactant gas distributor is provided in the chamber lid; and
a purge gas distributor for distributing purge gas to a purge gas distribution area defined between the source gas distribution area and the reactant gas distribution area, wherein the purge gas distributor is provided in the chamber lid,
wherein a distance between the purge gas distributor and the substrate is relatively smaller than a distance between the substrate and each of the source gas distributor and reactant gas distributor.

2. The substrate processing apparatus of claim 1, wherein the distance between the purge gas distributor and the substrate is less than the half of the distance between the source gas distributor and the substrate.

3. The substrate processing apparatus of claim 1, wherein the purge gas is non-reactive gas.

4. The substrate processing apparatus of claim 1, wherein the purge gas distributor includes:
a housing protruding out of the lower surface of the chamber lid toward the substrate, wherein the housing is detachably connected to the chamber lid, and the housing is provided with a purge gas distribution space for distributing the purge gas to the purge gas distribution area; and
a purge gas supply hole formed in the upper surface of the housing and communicated with the purge gas distribution space.

5. The substrate processing apparatus of claim 4, wherein both sides of the housing, which corresponds to the space between the source gas distributor and the reactant gas distributor, are formed in a fan shape.

6. The substrate processing apparatus of claim 4, wherein the purge gas distributor further includes a purge gas distribution pattern member for distributing the purge gas of the purge gas distribution space to the purge gas distribution area, wherein the purge gas distribution pattern member is provided in the lower surface of the housing.

7. The substrate processing apparatus of claim 1, wherein the chamber lid includes:
a lid frame for covering an upper side of the process chamber;
a first module receiver provided in the lid frame and formed in a hole shape corresponding to the source gas distribution area, wherein the source gas distributor is inserted into the first module receiver;
a second module receiver provided in the lid frame and formed in a hole shape corresponding to the reactant gas distribution area, wherein the reactant gas distributor is inserted into the second module receiver; and
a protruding part protruding out of the lower surface of the lid frame corresponding to the purge gas distribution area toward the substrate, wherein the purge gas distributor is formed in the protruding part.

8. The substrate processing apparatus of claim 7, wherein the purge gas distributor includes a plurality of purge gas distribution holes for distributing the purge gas to the purge gas distribution area, wherein the plurality of purge gas distribution holes are provided in the protruding part, and are formed at fixed intervals.

9. The substrate processing apparatus of claim 1, wherein the source gas distributor activates the source gas by the use of plasma, and distributes the activated source gas.

10. The substrate processing apparatus of claim 1, wherein the reactant gas distributor activates the reactant gas by the use of plasma, and distributes the activated reactant gas.

11. The substrate processing apparatus of claim 1, wherein a distribution pressure of the purge gas is relatively higher than each distribution pressure of the source gas and the reactant gas.

12. The substrate processing apparatus of claim 1, wherein a distribution quantity of the source gas is different from a distribution quantity of the reactant gas.

13. A substrate processing method for depositing a thin film on a substrate by a mutual reaction of source gas and reactant gas inside a process space prepared in a process chamber comprising:
placing at least one substrate on a substrate supporter provided inside the process chamber;
distributing the source gas to a source gas distribution area defined on the substrate supporter;
distributing the reactant gas to a reactant gas distribution area defined on the substrate supporter; and
distributing purge gas to a purge gas distribution area defined between the source gas distribution area and the reactant gas distribution area so as to spatially separate the source gas distribution area and the reactant gas distribution area from each other,
wherein a distribution distance of the purge gas to the substrate is relatively shorter than each distribution distance of the source gas and the reactant gas to the substrate.

14. The substrate processing method of claim 13, wherein the distribution distance of the purge gas to the substrate is less than the half of the distribution distance of the source gas to the substrate.

15. The substrate processing method of claim 13, wherein the purge gas is non-reactive gas.

16. The substrate processing method of claim 13, wherein the process of distributing the source gas includes activating the source gas by the use of plasma, and distributing the activated source gas.

17. The substrate processing method of claim 13, wherein the process of distributing the reactant gas includes activating the reactant gas by the use of plasma, and distributing the activated reactant gas.

18. The substrate processing method of claim 13, wherein a distribution pressure of the purge gas is relatively higher than each distribution pressure of the source gas and the reactant gas.

19. The substrate processing method of claim 13, wherein a distribution quantity of the source gas is different from a distribution quantity of the reactant gas.

20. The substrate processing method of claim 16, wherein the process of distributing the reactant gas includes activating the reactant gas by the use of plasma, and distributing the activated reactant gas.
